(19) United States
(12) Patent Application Publication
(10) Pub. No.: US 2007/0114604 A1
(43) Pub. Date: May 24, 2007

(54) Double-extension formation using offset spacer

(75) Inventors: Huan-Tsung Huang, Hsin-chu (TW); Liang-Kai Han, Hsinchu City (TW)

Correspondence Address: L. Howard Chen, Esq.;Kirkpatrick & Lockhart Preston Gates Ellis LLP, Suite 1700, 55 Second Street, San Francisco, CA, 94104, US

(73) Assignee: Taiwan Semiconductor Manufacturing Co., Ltd.

(21) Appl. No.: 11/286,003

(22) Filed: Nov. 22, 2005

(51) Int. Cl. H01L 21/336; H01L 29/76

(52) U.S. Cl. 257/335; 257/336; 438/306; 438/307; 257/408

(57) ABSTRACT

A MOS transistor structure is disclosed. A gate electrode is disposed on a semiconductor substrate. A first extension of a predetermined impurity type is substantially aligned with the gate electrode in the substrate. A second extension of the predetermined impurity type overlaps with the first extension in the substrate. The first extension has at least one lateral boundary line closer to the gate electrode than that of the second extension. Source and drain regions of the predetermined polarity type overlaps with the first and second extensions in the substrate. The second extension has at least one lateral boundary line closer to the gate electrode than that of the source and drain regions. The source and drain regions are deeper than the second extension, which is deeper than the first extension, so that they collectively reduce lateral abruptness of the source and drain, while maintaining a reduced extension resistance.

### BACKGROUND

The present invention relates generally to semiconductor devices, and more particularly to a method for implanting multiple extensions on a metal oxide semiconductor field effect transistor.

A MOSFET typically has three or four terminals. A three-terminal MOSFET includes a source, a drain, and a gate. A voltage applied to the gate terminal controls MOSFET channel resistance. The gate region, which is not a junction, is a metal oxide “sandwich” running the length of the channel surface. On the other hand, MOSFET source and drain regions are junctions and not simply contacts.

Taking an n-channel MOSFET for example, the source and drain are shallow n-type regions in an n-channel MOSFET. The gate material, such as polycrystalline silicon, is typically placed over a channel, but separated from the channel by a thin layer of insulating silicon dioxide. The channel is of a p-type material. With no bias voltage applied to the gate, the resistance of the path between the source and drain is high, and there will be no current flowing between the two regions. When an appropriate voltage is applied between the gate and source terminals, the electric field generated penetrates through the oxide and creates a so-called “inversion channel” in the channel underneath. Since the inversion channel is of the same type, i.e. P-type or N-type, as the source and drain, it provides a conduit (or the “channel”) through which current can pass. By varying the voltage between the gate and body, conductivity can be modulated.

Semiconductor device fabrication is a multiple-step sequence to create chips used in everyday electrical and electronic devices. Fabrication of a MOSFET normally includes a silicon substrate wafer as a starting base. A gate oxide is grown and polycrystalline silicon is added to create a gate. Light pattern is projected to photoresist and a chemical washes away material that is illuminated or shaded from the stencil depending on positive or negative exposure; this process is called developing. Ion implantation deposits N-type or P-type material to create a source and drain. Additionally the process can include many other steps such as phosphorus diffusion, annealing, and deposition of material to give the MOSFET a unique bias, resistive characteristics and properties.

However, conventional fabrication methods produce MOSFETs having not only a high resistance between the source, drain and diffusion channel, but also geometry issues in depth or spread related to diffusion during annealing. Furthermore, control issues may also be problematic.

As such, desirable in the art of semiconductor designs are additional MOSFET fabrication methods that provide more robust, more configurable MOSFETs.

### SUMMARY

In view of the foregoing, the following provides a method to enhance the source and drain layer resistance by using multiple lightly-doped extensions on the source and drain, and by making part of the heavily-doped extensions deep enough to provide more input and output conductivity.

In various embodiments, a MOS transistor structure is disclosed. A gate electrode is disposed on a semiconductor substrate. A first extension of a predetermined impurity type is substantially aligned with the gate electrode in the substrate. A second extension of the predetermined impurity type overlaps with the first extension in the substrate. The first extension has at least one lateral boundary line closer to the gate electrode than that of the second extension. Source and drain regions of the predetermined polarity type overlaps with the first and second extensions in the substrate. The second extension has at least one lateral boundary line closer to the gate electrode than that of the source and drain regions. The source and drain regions are deeper than the second extension, which is deeper than the first extension, so that they collectively reduce lateral abruptness of the source and drain, while maintaining a reduced extension resistance.

The construction and method of operation of the invention, however, together with additional objectives and advantages thereof will be best understood from the following description of specific embodiments when read in connection with the accompanying drawings.

### BRIEF DESCRIPTION OF THE DRAWINGS

FIG. 1 presents a cross sectional area of a conventional MOSFET structure.

FIGS. 2A-2C present a series of steps illustrating a method for constructing a MOSFET structure in accordance with the first embodiment of the present invention.

FIGS. 3A-3C present a series of steps illustrating a method for constructing a MOSFET structure in accordance with the second embodiment of the present invention.

### DESCRIPTION

The present disclosure provides methods for form double extension to improve the performance of transistors which will have less input and output resistance and a smoother source and drain layer transition. The following provides a detailed description of two methods for fabricating an improved MOSFET structure.

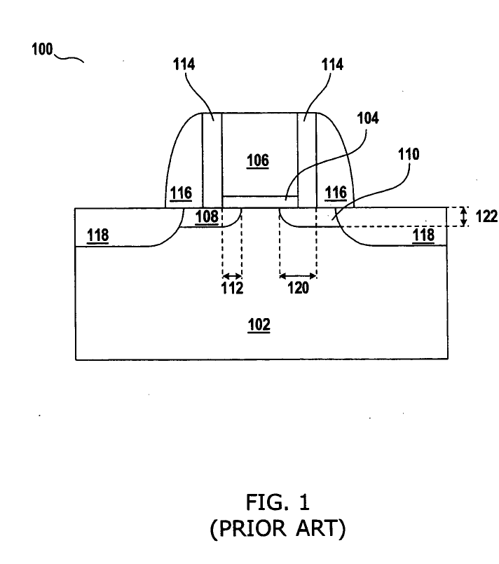

FIG. 1 presents a cross sectional area of a conventional N-MOSFET structure 100. Basic fabrication of such a conventional N-MOSFET structure 100 starts with a semiconductor substrate 102. The substrate 102 is doped with special impurities to form a P-type material. An oxide layer 104 is then formed on the substrate 102. A layer of gate material such as the polycrystalline silicon (poly) 106 is then deposited over the oxide layer 104. A photoresist coating (not shown) is typically applied to the substrate 102. After the substrate 102 is exposed to a light pattern, the photoresist coating wafer is developed. The exposed areas are dissolved if positive photoresist is used. A portion of the poly 106 is then etched, followed by the oxide layer 104. The above steps provide an “island” comprising the oxide layer 104 and the poly 106, which constitutes the N-MOSFET's gate electrode.

A source 108 and a drain 110 of the N-MOSFET are created by adding a lightly doped N-type material to the substrate 102 through implantation, which is typically performed by using an atomic accelerator. The implantation process deposits material near the surface and in a uniform process. The process also slightly damages the substrate 102. To fix the damage, the wafer is annealed, or heat treated, in order to modify the material's properties. However, a side effect of the annealing process is diffusion, which is caused by the natural migration of atoms from a more concentrated region to a less concentrated region. Generally, lateral diffusion is undesirable, however sometimes unavoidable, in semiconductor device fabrication as it causes lateral distortion of the device geometry and can create shorts or parasitic capacitance. A length 112 illustrates diffusion of the implanted material. The small overlap of length 112 of the N-type material and the poly 106 form a parasitic capacitance that changes the transistor's speed properties.

In semiconductor fabrication, the addition of layers of materials normally creates a parasitic capacitance between layers. This parasitic capacitance typically works against the design because it causes the transistor to turn on slowly as the parasitic capacitance charges up. A way to minimize parasitic capacitance resulting from lateral diffusion is to use various oxide offset spacers 114 which can be added to the vertical sides of the gate as an option, prior to a specific implant.

The half-completed transistor is then covered with an oxide material. The oxide is chemically etched away in such a way that only sidewall spacers 116 remain. This sidewall spacer 116 is used as a mask for additional selective implantations. Finally, a heavily doped N-type material is implanted and diffused to the substrate 102 to create a deep extension 118 at the source 108 and the drain 110.

The above steps explain the basic steps for making an N-MOSFET. Various ways of manufacturing a MOSFET exist and each depends on the desired properties of the transistor needed. A clear disadvantage from this conventional method is the lateral abruptness degradation with an increasing length 120. The surface area and volume taken by the lightly-doped material is not sufficient in many cases to form a good conductive medium for a required current density. This is due to a poor transition of the resistive properties of the materials used. Additionally, a depth 122 at any given length 112 may not be sufficient for the current flow when the gate is turned on. Another disadvantage is that the ratio between depth 122 and the length 120 ratio remains static. In addition, several annealing processes might encourage lateral diffusion along with vertical diffusion.

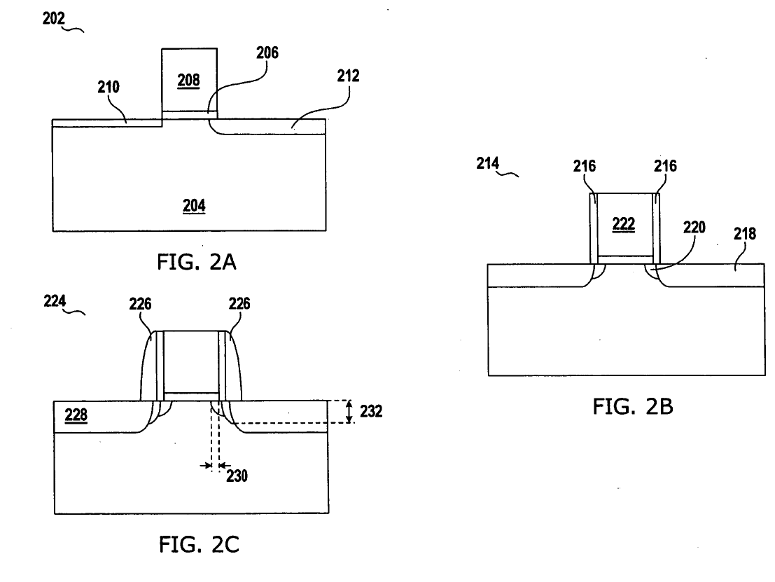

FIGS. 2A-2C present steps 202, 214 and 224 illustrating a method for constructing a MOSFET structure in accordance with the first embodiment of the present invention. In this embodiment, the MOSFET structure includes multiple lightly-doped extensions and one heavily-doped extension. In step 202, a semiconductor substrate 204 is doped with a P-type material after a gate structure is formed on the substrate 204. A gate having an oxide layer 206 and a poly 208 is fabricated by processes similar to those described in the fabrication of the N-MOSFET structure 100. The thickness of the oxide layer 206 can be between 0-20 angstroms. A first extension 210 is formed by implanting selected impurities to the substrate 204 as it is “masked” by the gate to create impurity regions which are the bases for the source and drain. This first extension 210 is lightly-doped with an N-type impurity material such as arsenic (As), and is relatively shallow in its depth. This can be done by a low energy source such as 5 KeV for As and BF₂, and <2 KeV for Boron, which is a P-type impurity material. The doping impurity dosage may be in a range between 5e13 and 1e16 cm-2. The first extension 210 is roughly aligned with the edges of the gate. In order to increase a dopant concentration in a localized area, a rapid heat treatment known as annealing is usually processed. Alternatively, this annealing process can be avoided and the desired dopant concentration can still be achieved, depending on the temperature during formation of a subsequent spacer is a later stage. After annealing, a portion of this first extension 210 extends both vertically and laterally. Laterally, it now extends beyond the edges of the gate and further underneath the gate. Vertically, the first extension region now has a bigger depth. This two-dimensional extension is caused by diffusion, thereby creating a high concentration extension 212. It is understood that for illustration purposes, only the extension 210 is illustrated on the left side of the gate, and only the extension 212 illustrated on the right side of the gate, but in fact, after the annealing, the extension on the left side should look like the extension 212.

In step 214, oxide offset spacers 216 are added to the vertical sidewalls of the gate, which have a width ranging from 50 to 400 angstroms. The oxide offset spacers 216 function as a mask for placing a second extension 218. The second extension 218 of the same type (i.e., using the same type of impurities) is implanted and further diffused through a heating process. This time, the depth of the second extension is deeper than the first extension. This depth is an important factor that affects the resistance of the source and drain. This second extension overlapping the first extension creates a gradual increase in conductivity to the increasing geometric depth and the concentration created by extensions 218 and 220. The extension 220 diffuses under the oxide offset spacers 216, thereby minimizing a parasitic capacitance from being created.

In step 224, the top surface of the transistor-in-process is covered with an oxide. The oxide is etched in such a way where only sidewall spacers 226 remain. Like the oxide offset spacers, the sidewall spacers 226 are formed to function as a mask to self align the source and drain regions 228. The source and drain 228 are implanted and diffused through a heating process. The source and drain are heavily doped with an N-type impurity material. As it is seen, from the first extension to the third extension, each succeeded extension is implanted at a higher energy in order to create a deeper layer.

Advantages of using this fabrication technique arise from the gradual geometric size and impurity material concentration of the extensions, from small to large. This process benefits from rapid thermal processes or the use of high temperature sub-melt laser annealing which can contribute to diffusion-less profiles. Additionally, the fabrication of a transistor with a minimal diffusion distance 230 caused by lateral diffusion and an increase in an extension depth 232 can substantially reduce input and output resistance related to the source and the drain. It is understood that the abruptness of the extension of the source and drain is measured by the lateral diffusion distance 230. As it can be seen on the drawings, the overlapping area between the first and second extension that extends out and underneath the gate structure and the spacers provides a “two-step” decline in depth instead of one step as in the conventional practice. It is said that the two-step decline reduces the overall abruptness of the extension.

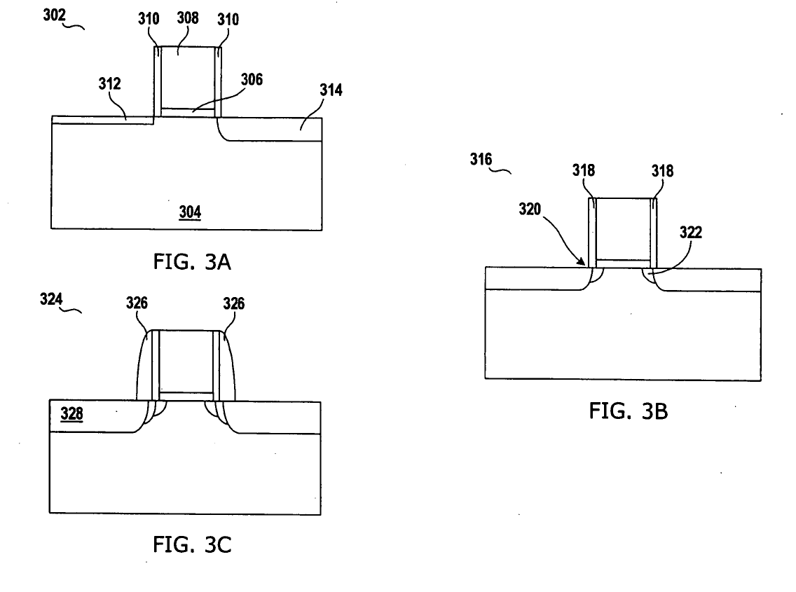

FIGS. 3A-3C present steps 302, 316, and 324 illustrating a method for constructing a MOSFET structure in accordance with the second embodiment of the present invention. In this embodiment, the MOSFET structure includes multiple lightly-doped extensions and a heavily-doped extension. In step 302, a semiconductor substrate 304 is doped with a P-type material. The gate includes an oxide layer 306 and a poly 308, which are fabricated using similar processes as described in the fabrication of the N-MOSFET structure 100. The sidewalls of the gate are first covered with an oxide to create thick offset spacers 310. A first layer 312 of N-type impurity material is implanted to the substrate 304 to create the base for the extension. The wafer is then annealed and a portion of the first layer 312 diffuses slightly to form a first extension 314. The edges of the first extension 314 are substantially aligned with the spacers 310.

In step 316, the oxide offset spacers 310 are thinned by etching, thereby forming thinned spacers 318, which have widths narrower than those of the original “thick” spacers 310. The thinned spacers 318 is intended to help align a shallow implantation of impurities. The etching process creates a new shadow line, as depicted at a corner 320 between the edge of the oxide offset spacer 318 and the surface of the substrate 304 that will become the implant edge for the next extension. A thin layer of lightly-doped N-type impurity material is then implanted and diffused, thereby creating a thin extension 322. At this point, the extension for the source and drain is appropriately formed by the overlapping first and second extension, both formed by having the same type of impurities. As it can be seen from FIG. 3B, the abruptness of the edges underneath the gate is reduced due to the separate engineering of the first and second extensions. Like the one depicted in FIGS. 2A-2C, a two-step decline has been formed.

In step 324, the surface of the transistor is covered with an oxide. The oxide is etched in such a way where only sidewall spacers 326 remain. The source and drain 328 are then implanted and diffused. The source and drain 328 includes a heavily-doped N-type material. The source and drain are implanted at a higher energy in order to create a deeper layer.

The need to implant the thin extension 322 only after implanting the first extension 314 is due to a concern with the thermal budget, or the exposure to fabrication heat cycles. This method can reduce transient enhanced diffusion or damage caused to the crystal during diffusion under the high energies of implantation. The reduction in exposure reduces diffusion of dopant in the source and drain 328, as well as the gradual diffusion of the source and drain layers due to annealing into the inversion channel area, which can cause a punch through if “smeared” long enough.

In various embodiments, the fabrication method specifically mentions N-MOSFET. While examples are given for N-MOSFET, it is understood by those skilled in the art that a P-MOSFET can also be fabricated using the same methods. Moreover, while only the basic steps to MOSFET fabrication are illustrated, additional steps are contemplated for changing a MOSFET's properties to match a given design requirement.

This invention proposes a novel method that uses multiple extensions of different geometries and concentrations. The transistor created by the present invention provides an (source/drain) extension profile that has a minimum lateral diffusion, while achieving minimal extension resistance by having deep vertical diffusion. Advantages of the invention include less diffusion with special low heat anneal processes and deeper source and drain geometries at the outer extremities, thereby leading to more conductivity or less resistance. Multiple extensions may be essential to achieve both short channel control and low extension resistance and thus high drive current.

The above illustration provides many different embodiments or embodiments for implementing different features of the invention. Specific embodiments of components and processes are described to help clarify the invention. These are, of course, merely embodiments and are not intended to limit the invention from that described in the claims.

Although the invention is illustrated and described herein as embodied in one or more specific examples, it is nevertheless not intended to be limited to the details shown, since various modifications and structural changes may be made therein without departing from the spirit of the invention and within the scope and range of equivalents of the claims. Accordingly, it is appropriate that the appended claims be construed broadly and in a manner consistent with the scope of the invention, as set forth in the following claims.

What is claimed is:

1. A method for constructing a metal-oxide-semiconductor field effect transistor (MOSFET) structure with multiple doped source/drain extensions, the method comprising:
forming a gate electrode on a semiconductor substrate;
forming a first extension of a predetermined impurity type substantially aligned with the gate electrode in the substrate;
forming one or more first set of spacers on sidewalls of the gate electrode;
forming a second extension of the predetermined impurity type substantially aligned with the first set of spacers and overlapping with the first extension in the substrate;
forming one or more second set of spacers laterally onto the first set of spacers; and
forming source and drain regions of the predetermined impurity type overlapping with the first and second extensions and substantially aligned with the second set of spacers in the substrate,
wherein the first set of spacers help to align the first and second extensions so that they collectively reduce lateral abruptness of the source and drain, while maintaining a reduced extension resistance.

2. The method of claim 1 wherein the first extension is shallower than the second extension.

3. The method of claim 2 wherein the first extension has at least one lateral boundary line closer to the gate electrode than that of the second extension.

4. The method of claim 3 wherein the second extension has an impurity concentration no smaller than that of the first extension.

5. The method of claim 4 wherein the impurity concentration of the first extension approximately ranges from 5e13 to 1e16 cm-2.

6. The method of claim 4 wherein the impurity concentration of the second extension approximately ranges from 1e14 to 1e16 cm-2.

7. The method of claim 1 wherein the first extension is formed using the gate electrode for alignment.

8. The method of claim 1 wherein the second extension is formed using the first set of spacers for alignment.

9. The method of claim 1 wherein the first extension controllably defines a lateral diffusion distance underneath the gate electrode.

10. A metal-oxide-semiconductor field effect transistor (MOSFET) structure with multiple doped source/drain extensions, comprising:
a gate electrode disposed on a semiconductor substrate;
a first extension of a predetermined impurity type substantially aligned with the gate electrode in the substrate;
a second extension of the predetermined impurity type overlapping with the first extension in the substrate, the first extension having at least one lateral boundary line closer to the gate electrode than that of the second extension;
source and drain regions of the predetermined polarity type overlapping with the first and second extensions in the substrate, the second extension having at least one lateral boundary line closer to the gate electrode than that of the source and drain regions,
wherein the source and drain regions are deeper than the second extension, which is deeper than the first extension, so that they collectively reduce lateral abruptness of the source and drain, while maintaining a reduced extension resistance.

11. The MOSFET structure of claim 10 wherein the second extension has a predetermined impurity concentration no smaller than that of the first extension.

12. The MOSFET structure of claim 11 wherein the predetermined impurity concentration of the first extension approximately ranges from 5e13 to 1e16 cm-2.

13. The MOSFET structure of claim 11 wherein the predetermined impurity concentration of the second extension approximately ranges from 1e14 to 1e16 cm-2.

14. The MOSFET structure of claim 10 further comprising one or more first set of spacers on the side walls of the gate electrode.

15. The MOSFET structure of claim 16 further comprising one or more second set of spacers laterally formed onto the first set of spacers.

16. A method for constructing a metal-oxide-semiconductor field effect transistor (MOSFET) structure with multiple doped source/drain extensions, the method comprising:
forming a gate electrode on a semiconductor substrate;
forming one or more first set of spacers on sidewalls of the gate electrode;
forming a first extension of a predetermined impurity type substantially aligned with the first set of spacers in the substrate;
thinning the first set of spacers;
forming a second extension of the predetermined impurity type substantially aligned with the first set of thinned spacers and overlapping with the first extension in the substrate;
forming one or more second set of spacers laterally onto the first set of spacers; and
forming source and drain regions of the predetermined impurity type overlapping with the first and second extensions and substantially aligned with the second set of spacers in the substrate,
wherein the first set of spacers help to align the first and second extensions so that they collectively reduce lateral abruptness of the source and drain, while maintaining a reduced extension resistance.

17. The method of claim 16 wherein the second extension is shallower than the first extension.

18. The method of claim 17 wherein the second extension has at least one lateral boundary line closer to the gate electrode than that of the first extension.

19. The method of claim 16 wherein the second extension has a predetermined impurity concentration approximately ranging from 5e13 to 1e16 cm-2.

20. The method of claim 16 wherein the first extension has a predetermined impurity concentration approximately ranging from 1e14 to 1e16 cm-2.
